(19) United States
(12) Patent Application Publication
(10) Pub. No.: US 2026/0018390 A1
(43) Pub. Date: Jan. 15, 2026

(54) APPARATUS AND METHOD FOR ATOMIC LAYER ETCHING BASED ON CONTROL OF CHARGED PARTICLES

(71) Applicant: INFOVION INC., Bucheon-si (KR)

(72) Inventor: Yong Hwan KIM, Goyang-si (KR)

(21) Appl. No.: 19/334,639

(22) Filed: Sep. 19, 2025

Related U.S. Application Data
(63) Continuation-in-part of application No. PCT/KR2024/003326, filed on Mar. 18, 2024.

(30) Foreign Application Priority Data
Apr. 3, 2023 (KR) 10-2023-0043650

(51) Int. Cl. H01J 37/32; H01L 21/3065

(52) U.S. Cl. CPC H01J 37/32669; H01L 21/3065; H01J 2237/002; H01J 2237/04732; H01J 2237/04753; H01J 2237/152; H01J 2237/334

(57) ABSTRACT

Provided is an atomic layer etching apparatus comprising: a plasma source; a grid assembly composed of a plurality of grids to which potentials can be applied, disposed at the front of the plasma source, and configured to extract charged particles from the plasma; and a magnetic field applying module configured to apply a magnetic field to a flight space of the charged particles so that the charged particles are obliquely incident on a target substrate at a preset angle. The charged particles extracted from the plasma by the grid assembly fly while rotating with a preset curvature by the magnetic field and are obliquely incident on the substrate. As a result, the apparatus limits the collision energy of the charged particles when they are incident on the substrate, thereby enabling atomic layer etching of the target substrate.

### TECHNICAL FIELD

The present invention relates to an atomic layer etching apparatus and method, and more particularly, to an atomic layer etching apparatus and method characterized in that atomic layer etching is performed while controlling charged particles using a magnetic field and an electric field in order to reduce the etch depth caused by ion collision or to adjust the energy of the charged particles.

### BACKGROUND ART

In the era of the Fourth Industrial Revolution, semiconductors are attracting attention as key components embedded in smart devices, artificial intelligence, 5G, IoT, and vehicles. Accordingly, how many devices can be implemented within a limited space has become an even more important issue. Therefore, semiconductor miniaturization technology has recently been advancing. In particular, according to Moore's law, semiconductor manufacturing processes have been developing in the direction of reducing line width and achieving higher integration. Furthermore, the development of low-power and high-performance system semiconductors has been further accelerated in recent years.

As described above, in semiconductors manufactured through fine processes, more transistors are densely packed in a small area, thereby reducing the distance and time for electrons to move, and as a result, operating faster with lower energy consumption. However, as the scale of the transistor critical dimension is reduced, the aspect ratio of the pattern increases, and problems of pattern damage occurring during the patterning process have become prominent. Therefore, there is an increasing demand for fine etching processes capable of solving these problems.

In response to such industrial demands, companies such as Samsung, TSMC, and Intel are accelerating technology development for entering the 2 nm process, which is finer than the 3 nm process that Samsung has recently begun mass production of. As a result, the demand for damage-free etching technology is further increasing.

Etching methods used in semiconductor manufacturing processes include chemical etching, sputter etching, reactive ion etching (hereinafter referred to as “RIE”), and atomic layer etching (hereinafter referred to as “ALE”).

The chemical etching occurs by a chemical reaction generated as the radical density becomes higher than that of ions as the pressure increases. Since the chemical etching proceeds by reacting with a specific material through a chemical reaction, it exhibits very good selectivity. However, the chemical etching is isotropic, making it difficult to control the etching direction, and as a result, causing an undercut phenomenon.

The sputter etching is a physical etching method in which ions are accelerated and the accelerated high-energy ions collide with a target substrate. As the pressure decreases, the density of ions becomes higher than that of radicals, thereby increasing the efficiency of sputter etching caused by ion collision. The sputter etching has the advantage that the etching process can be controlled in a desired direction by adjusting the incident angle of ions having linearity. However, the sputter etching has the disadvantage of poor selectivity because etching occurs by direct physical collision without a process of chemically reacting with a specific material.

The reactive ion etching (RIE) is a process that combines the chemical etching method and the sputter etching method to compensate for the disadvantages of both methods. Accordingly, in reactive ion etching, highly reactive radicals chemically react with the thin film material to generate a compound, and ions collide with the compound to break the underlying bonds and cause an etching reaction. RIE provides fast anisotropic etching and high selectivity. However, since ions and radicals simultaneously affect the etching reaction, RIE has the disadvantage that a difference in etching depth occurs depending on the etching area. In addition, because RIE uses accelerated ions for etching, it is difficult to remove only the target material, and as a result, it has the disadvantage of causing damage to the device.

Meanwhile, in recent semiconductor processes, process precision at the atomic level has been required. In response to such demands, development of fine process technology that can improve device reliability and production yield by preventing substrate damage during the etching process has been accelerated. In the RIE process, ions in the plasma are incident on the substrate with high energy. Ion collisions occurring in this process interfere with the adsorption of reactive radicals, thereby causing substrate damage such as lattice defects and ion implantation. Substrate damage causes problems such as pattern damage and deterioration of the electrical characteristics of semiconductor devices, and as a result, has a fatal adverse effect on process yield and product reliability.

Another challenge in fine etching processes is that only the target material must be removed without removing the underlying material. In the case of a film stack structure having layers other than the upper layer, it is necessary to remove only the upper layer without removing or damaging the layers beneath the upper layer, and therefore high selectivity is required.

In order to overcome the problems of the aforementioned conventional processes, the atomic layer etching (ALE) process is used. The atomic layer etching process can uniformly remove the deposited thin film material on an atomic layer basis by temporally separating the chemical reaction and the physical reaction occurring in the etching process. The ALE process proceeds by being divided into an adsorption step and a desorption step. The adsorption step is a process of adsorbing reactive radicals onto the substrate to form a surface layer compound. The desorption step is a process of removing the material to be etched while generating byproducts due to ion collisions. In order to implement an etching process without the damage of the thin film, in the adsorption step of reactive radicals, the etching rate is controlled by adjusting the characteristics of chemical reactions on the surface depending on the plasma generation method. In addition, in order to implement an etching process without the damage of the thin film, in the desorption step, the correlation between plasma density and ion energy is adjusted.

Companies such as LAM and AMAT in the United States are developing the etching equipment for precision processes without the damage of the substrate. LAM is a company that ranks first and second in the etching and deposition equipment markets, respectively, and currently occupies most of the etching equipment market. In particular, companies such as LAM, AMAT, and ASM are conducting research on various ALE processes.

In the aforementioned ALE process, etching by ion collision is required. However, there is a limitation in lowering the energy of ions generated from plasma. In order to overcome such a limitation, research is being conducted on an ALE process that lowers ion energy by using microwave plasma operating even at low pressure.

Hereinafter, the ALE process will be described in more detail. The ALE process refers to a process of etching on a single atomic layer basis, in which the reactions of ions and radicals are time-divided to proceed with the process. FIG. 1 is a schematic diagram illustrating the concept of the atomic layer etching process. As shown in FIG. 1, the ALE process sequentially proceeds through an adsorption step, a first purging step, a desorption step, and a second purging step.

The adsorption step is a step in which radicals generated from plasma, which react with the substrate material, move to the substrate surface through diffusion and are adsorbed onto the substrate surface to form a surface layer compound. At this time, similar to the atomic layer deposition (ALD) process, the reactant is adsorbed onto the entire surface of the substrate, but once one atomic layer of the surface is adsorbed, the surface reaction becomes saturated and does not proceed further, thereby causing a self-limited surface reaction and suppressing additional reactions.

The first purging step is a step of pumping and removing residual reactants, such as radicals remaining in the upper space without reacting, after the adsorption has proceeded.

The desorption step is a step in which compounds formed by the reaction of the substrate uppermost atoms with the adsorbed species during the adsorption are separated from the substrate surface by ions incident from above. At this time, the binding energy of the substrate material and the binding energy of the reacted compound thin film are calculated, and ions having an energy greater than the binding energy of the substrate material are collided with the substrate surface. If the ion energy is low, the compound thin film may be incompletely removed. On the other hand, if the ion energy is high, the lower layer of the compound thin film may be deeply etched, and thus may be removed similarly to sputtering. Therefore, in order to etch only the surface atomic layer, it is very important to find a process window by precise control of the ion energy.

The second purging step is a step of pumping using gas to remove the material desorbed from the substrate. Plasma has its own plasma density depending on the discharge method and discharge conditions, and the higher the plasma density, the higher the Tₑ (electron temperature). In addition, when Tₑ is high, the plasma sheath potential increases, and thus the collision energy of ions flying from the plasma toward the substrate becomes large. The high collision energy of ions induces deep etching, which is not suitable for the ALE process intended to etch only a single atomic layer on the substrate surface. In addition, the high collision energy of ions not only causes damage to the substrate to be etched but also results in the etched surface having poor smoothness in roughness.

Meanwhile, ions flying through the sheath of plasma originate from the plasma, which exhibits collective behavior formed by electrons colliding and creating ions mixed together. Accordingly, ions flying through the sheath of plasma have energies corresponding to the sheath potential, ranging from several tens of eV to several hundreds of eV. In the case where an electric field is applied to a grid having multiple grid holes to extract ions from plasma, the ions must overcome the attraction of the plasma exhibiting collective behavior and escape from the plasma, and thus they escape with energy of about 100 eV or more.

Meanwhile, in the ALE process, the energy of argon ions required to etch a single atomic layer has a relatively low value of 25 eV to 70 eV. At this time, since the binding energy differs depending on the type of material to be etched, the ion energy required to etch a single atomic layer can be determined according to the type of material to be etched.

In order to generate etching ions having such low ion energy, it is necessary to create a low plasma density having a low Tₑ value, and to satisfy this, plasma generated at low pressure (i.e., high vacuum) is required. Recently, research has been conducted using microwaves to generate plasma that can be maintained even at such low pressure and applied to the ALE process.

Meanwhile, the atomic layer etching process involves the following problems.

FIG. 2 is a Gaussian distribution graph showing the form of the ion beam energy distribution extracted from plasma. When etching a Si crystal, the energy of Ar ions required to etch a single Si atomic layer is 50 eV. This is about ten times the Si—Si bond energy of 4 eV. However, the ions extracted from plasma have energies exceeding a 50 eV. In addition, as shown in FIG. 2, ions extracted from plasma have a Gaussian distribution in which the energy distribution is widely spread. Meanwhile, the basic energy of ions that can be extracted from plasma, which is a general ion source, is 100 eV or more. Therefore, among the ions extracted from plasma having a broad energy distribution, ions exceeding 50 eV form a collision cascade deeper than a single Si atomic layer, thereby causing a deep etch. For these reasons, in order to etch a single atomic layer in the ALE process, the etching ions must be controlled to have low energy, and the energy of the etching ions must have the characteristic of a single energy rather than a broad energy distribution.

FIG. 3 is a schematic diagram showing that, in a conventional atomic layer etching apparatus, an ion beam extracted from a plasma source is incident vertically on the surface of a substrate. The energy of ions coming through the plasma sheath or ions extracted through a grid is too strong to etch a single atomic layer. Therefore, as shown in FIG. 3, when ions extracted from plasma are directly used, undesired deep etching may occur. In addition, when ions having a broad gaussian energy distribution from plasma are used, undesired deep etching may occur due to ions having energies exceeding the energy required for single atomic layer etching.

In particular, a conventional ion beam source that uses gas ions extracted from plasma for ALE application has the following problems. The first problem is that an ion beam directly extracted from plasma has high energy. When ion charges are extracted with a potential difference exceeding the plasma potential, the energy of the ion beam becomes at least over 100 eV. In addition, higher energy is required in order to increase flux. Therefore, the conventional ion beam source is not suitable for use as a tool for atomic layer etching.

The second problem is that the ion beam energy extracted from the ion beam source does not have a single energy but forms a broad gaussian distribution. As described above, in the ALE process, it is necessary for the ion beam to have a single energy that etches only the surface atomic layer and is limited from causing deep etching below the surface atomic layer. However, the ion energy emitted from the ion beam source is widely dispersed in the form of a Gaussian distribution. Therefore, when using a conventional ion beam source, a collision cascade caused by ion collisions occurs beyond the single atomic layer of the surface down to the deep layers, resulting in deep etching problems. As a result, for atomic layer etching, an ion beam having a single energy value is required, and an ion beam with low energy is needed to etch only a single atomic layer of the surface without causing deep etching.

### SUMMARY OF THE INVENTION

In order to solve the aforementioned problems, the present invention is intended to provide an atomic layer etching apparatus and method capable of efficiently performing atomic layer etching on a target substrate by filtering ion beams flying at unspecified incident angles to irradiate only ion beams flying in the vertical direction, and simultaneously applying a magnetic field so that the ion beams are incident on the target substrate at a low incident angle capable of etching only the surface atomic layer.

In order to achieve the above technical objects, an atomic layer etching apparatus according to a first aspect of the present invention comprises: a plasma source for generating plasma; a grid assembly composed of a plurality of grids to which potentials can be applied, disposed in front of the plasma source, and configured to extract charged particles from the plasma of the plasma source by controlling potentials applied to the grids; and a magnetic field applying module disposed in a region adjacent to a flight space of the charged particles extracted from the plasma, the magnetic field applying module being configured to apply a magnetic field to the flight space of the charged particles, wherein the magnetic field applying module is configured to apply a magnetic field to the flight space of the charged particles so as to control flight paths of the charged particles, thereby enabling etching of a single atomic layer of the target substrate.

In the atomic layer etching apparatus according to the first aspect of the present invention, it is preferable that the magnetic field applying module is configured to adjust a strength and direction of the magnetic field applied to the flight space of the charged particles, such that the charged particles are obliquely incident on a surface of the target substrate at a preset incident angle.

In the atomic layer etching apparatus according to the first aspect of the present invention, it is preferable that the apparatus further comprises a ceramic grid made of a ceramic material to which no potential is applied, the ceramic grid being disposed at a predetermined distance from a front surface of the grid assembly, wherein the ceramic grid, to which no potential is applied, allows the charged particles extracted from the plasma to fly with uniform energy and linearity.

In the atomic layer etching apparatus according to the first aspect of the present invention, it is preferable that the apparatus further comprises a metal layer disposed on one surface of the ceramic grid and disposed at a predetermined distance from grid holes of the ceramic grid, wherein the atomic layer etching apparatus is configured to apply a potential to the metal layer so as to adjust the potential of the charged particles emitted from the ceramic grid.

In the atomic layer etching apparatus according to the first aspect of the present invention, it is preferable that the magnetic field applying module is formed by combining one or more of an electromagnet surrounding a magnet core, a circular or rectangular type Helmholtz coil, a flat electromagnet, one or multiple magnet cores and coils.

In the atomic layer etching apparatus according to the first aspect of the present invention, it is preferable that the magnetic field applying module is disposed at one or more of a front side, a rear side, a left side, a right side, an upper side, and a lower side of a space where the magnetic field is required.

In the atomic layer etching apparatus according to the first aspect of the present invention, it is preferable that the grid assembly comprises: a beam grid disposed adjacent to the plasma and configured to impart energy to charged particles of the plasma; an acceleration grid disposed at a predetermined distance from the beam grid and configured to extract and accelerate the charged particles from the plasma; and a deceleration grid disposed at a predetermined distance from the acceleration grid and configured to decelerate the charged particles extracted from the acceleration grid; wherein grid holes of the beam grid, the acceleration grid, and the deceleration grid are aligned with each other, and the charged particles are extracted from the plasma through the grid holes of the beam grid, the acceleration grid, and the deceleration grid.

In the atomic layer etching apparatus according to the first aspect of the present invention, it is further preferable that the deceleration grid is made of μ-metal capable of shielding a magnetic field or a magnetic material capable of shielding a magnetic field.

In the atomic layer etching apparatus according to the first aspect of the present invention, it is preferable that the grids included in the grid assembly are made of one material selected from a conductive metal, Si, SiC, Si₃N₄, and graphite.

In the atomic layer etching apparatus according to the first aspect of the present invention, it is preferable that a gas supplied to the plasma source is selected from one of He, Ne, Ar, Kr, and Xe according to energy required for atomic layer etching of the target substrate.

In the atomic layer etching apparatus according to the first aspect of the present invention, it is preferable that the apparatus further comprises a substrate cooling module configured to cool the target substrate, wherein the apparatus is configured to cool the target substrate while irradiating an electron beam onto a surface of the target substrate, such that only the surface temperature of the target substrate increases even when the electron beam is irradiated.

In order to achieve the above technical objects, an atomic layer etching apparatus according to a second aspect of the present invention comprises: a plasma source for generating plasma; a grid assembly composed of a plurality of grids to which potentials can be applied, disposed in front of the plasma source, and configured to extract charged particles from the plasma of the plasma source by controlling potentials applied to the grids; and a ceramic grid made of a ceramic material to which no potential is applied, disposed at a predetermined distance from a front surface of the grid assembly; wherein the charged particles extracted from the plasma source by the grid assembly are guided toward a target substrate with linearity by the ceramic grid so as to perform atomic layer etching of the target substrate.

In the atomic layer etching apparatus according to the second aspect of the present invention, it is preferable that the apparatus further comprises a metal layer disposed on one surface of the ceramic grid and disposed at a predetermined distance from the grid holes of the ceramic grid, wherein the atomic layer etching apparatus is configured to apply a potential to the metal layer so as to control the potential of the charged particles emitted from the ceramic grid.

In the atomic layer etching apparatus according to the second aspect of the present invention, it is preferable that the grid assembly comprises: a beam grid disposed adjacent to the plasma and configured to impart energy to charged particles of the plasma; an acceleration grid disposed at a predetermined distance from the beam grid and configured to extract and accelerate the charged particles from the plasma; a deceleration grid disposed at a predetermined distance from the acceleration grid and configured to decelerate the charged particles extracted from the acceleration grid; wherein grid holes of the beam grid, the acceleration grid, and the deceleration grid are aligned with each other, and the charged particles are extracted from the plasma through the grid holes of the beam grid, the acceleration grid, and the deceleration grid.

In order to achieve the above technical objects, an atomic layer etching method according to a third aspect of the present invention comprises the steps of: (a) adsorbing reactive radicals on a surface of a target substrate to form a surface layer compound on the target substrate; (b) removing residual reactants remaining unreacted after the adsorption; (c) etching the surface of the target substrate using an ion beam to desorb the surface layer compound from the target substrate; and (d) removing a material desorbed from the target substrate; wherein in step (c), a magnetic field having a preset direction and strength is applied to a flight space of the ion beam extracted from plasma and incident on the surface of the target substrate, such that the ion beam is obliquely incident on the surface of the target substrate at a preset incident angle.

In the atomic layer etching method according to the third aspect of the present invention, it is preferable that in step (c), the ion beam is obliquely incident on the surface of the target substrate while sequentially changing a direction of the magnetic field applied to the flight space of the ion beam, thereby uniformly etching the surface of the target substrate.

In the atomic layer etching method according to the third aspect of the present invention, it is preferable that step (a) comprises: (a1) extracting an electron beam from plasma; and (a2) applying a magnetic field having a preset direction to a flight space of the electron beam extracted from the plasma so that the electron beam is obliquely incident on the surface of the target substrate at a preset incident angle; wherein the surface temperature of the target substrate is raised by the electron beam obliquely incident on the surface of the target substrate.

In the atomic layer etching method according to the third aspect of the present invention, it is preferable that in step (a2), the electron beam is obliquely incident on the surface of the target substrate while sequentially changing a direction of the magnetic field applied to the flight space of the electron beam, thereby uniformly raising the surface temperature of the target substrate.

In the atomic layer etching method according to the third aspect of the present invention, it is preferable that step (a) further comprises the step of (a4) cooling the target substrate while obliquely irradiating the electron beam onto the surface of the target substrate; thereby raising only a surface temperature of the target substrate and forming a surface layer compound by bonding of only surface atoms of the target substrate.

When ions extracted from plasma through a grid assembly fly vertically toward a target substrate using a conventional ion beam source, the ion beam has energy that is too high to etch only a single atomic layer of the surface of the target substrate. This is because only ions having an energy greater than at least the critical energy corresponding to the mutual attraction of charged particles in the plasma can be extracted from the plasma. However, such critical energy is too high to etch only a single atomic layer of the surface of the target substrate.

Therefore, the atomic layer etching apparatus and method according to the present invention make it possible to decelerate the etching rate as if etching at a low incident angle capable of etching only a single atomic layer, by lowering the collision incident angle of the ions having high energy. As a result, efficient etching can be achieved by eliminating surface damage and etching the surface smoothly.

In addition, the atomic layer etching apparatus and method according to the present invention can heat only the surface of the substrate by inclined irradiation of an electron beam in the adsorption step, and at the same time allow radicals to react with the atoms of the heated substrate surface. As a result, adsorption and reaction of radicals on the atomic layer of the heated substrate surface can be made more effective, and compounds are formed only on the surface atomic layer, thereby producing a smooth surface after etching.

FIG. 4 is a schematic diagram defining the incident angle of an ion beam with respect to the surface of a target substrate, and FIG. 5 is a graph showing the relationship between the incident angle of the ion beam according to gas particles and the sputtering yield. Referring to FIG. 5, it can be seen that as the incident angle of the ion beam decreases, the etching rate decreases. In addition, as the incident angle of the ion beam decreases, ions are prevented from penetrating into the target substrate in the depth direction, thereby reducing substrate damage such as lattice defects and ion implantation.

The charged particles including ions or electrons extracted from plasma through the grid fall vertically toward the target substrate. When a magnetic field is applied in the vertical direction (±X, ±Y) with respect to the falling direction to the charged particles falling vertically to the substrate surface, the falling charged particles perform rotational flight. At this time, by adjusting the magnetic field so that the rotation radius of the charged particles matches the distance to the substrate, the charged particles in rotational flight are obliquely incident on the substrate at a low angle.

The atomic layer etching apparatus according to the present invention reduces the incident angle of the charged particles by applying a magnetic field perpendicular to the falling direction of the charged particles, thereby inducing the rotation of charged particles, even if the energy of the charged particles extracted from plasma is high. As a result, the vertical vector component of the charged particles is reduced, thereby eliminating damage to the substrate and maintaining a low etching rate by the charged particles.

Meanwhile, the atomic layer etching apparatus and method according to the present invention can adjust the incident angle by controlling the strength of the magnetic field even if the energy of the ion beam is constant, thereby generating various vertical vector components of energy. As a result, by adjusting the required energy according to the material to be etched, various types of materials can be etched. The method according to the present invention can be applied not only to ALE but also to thick film etching, enabling etching without damage to the substrate and providing a smooth etched surface.

Meanwhile, a mechanical method of making the ion beam incident on the substrate at a low angle can be simply implemented by arranging the ion beam source obliquely toward the substrate. However, in the case of a large-size ion beam source, it is structurally almost impossible to arrange the large ion beam source at an oblique angle with respect to the substrate to form a low angle while allowing the ion beam to be incident at the same distance with uniform flux on the substrate.

Therefore, the atomic layer etching apparatus according to the present invention can maintain the collision angle of the charged particles low by the magnetic field applying module, and at the same time, by changing the direction of the magnetic field, the charged particles can be oscillated while changing the direction of collision on the substrate to forward, backward, left, and right. The direction of the magnetic field can be changed by sequentially applying forward and reverse currents to the electromagnet of the magnetic field applying module.

As described above, the atomic layer etching apparatus according to the present invention continuously changes the direction of the magnetic field to left and right (±X) and forward and backward (±Y) and applies it to the ion beam, thereby continuously changing the incident direction of the ion beam, which is obliquely incident at a low angle toward the substrate, to forward, backward, left, and right. Accordingly, not only can etching of atoms on the substrate surface be effectively induced, but also the roughness of the etched surface can be improved.

In addition, the atomic layer etching apparatus according to the present invention can apply various forms of magnetic fields using the magnetic field applying module. Furthermore, the atomic layer etching apparatus according to the present invention can uniformly etch the entire surface of the substrate according to the distribution of the magnetic field by rotating the holder of the target substrate using the rotation module.

Meanwhile, the atomic layer etching apparatus according to the present invention further comprises a ceramic grid to which no potential can be applied, thereby filtering only ion beams having linearity. As a result, among the ions dispersed in a gaussian energy distribution, only ions having the vertical vector component energy corresponding to the ion energy applied to the beam grid can be filtered. Consequently, the linearity of the ion beam can be secured while reducing the energy dispersion of the ion beam. In addition, all ions incident in rotation reach the substrate surface with the same inclined angle while forming the same radius due to the applied magnetic field.

In addition, the atomic layer etching apparatus according to the present invention can apply a positive (+) or negative (−) potential field to ions flying toward the substrate through the ceramic grid by coating a metal layer on the front surface of the ceramic grid with a spacing from the sidewalls of the grid holes. While the ions pass through the ceramic grid having no potential, they are not affected by the potential applied to the metal layer, but during the flight after passing through the ceramic grid, they can be affected by the potential of the metal layer. As a result, the energy of the ion beam incident on the surface of the target substrate can be precisely adjusted by additionally increasing the energy of positive ions using a positive potential or additionally lowering the energy of positive ions using a negative potential.

In addition, in the atomic layer etching method according to the present invention, in the adsorption step, the surface of the target substrate is irradiated obliquely with an electron beam through the upper surface of the substrate to limit the penetration depth of the electron beam, and the lower portion of the substrate is cryogenically cooled using a cooling system, thereby heating only the surface of the substrate by electron beam collision. Then, by heating only the surface of the target substrate and simultaneously adsorbing and reacting radicals on the surface atomic layer of the target substrate, a surface layer compound can be formed limitedly only on the surface of the substrate. As a result, the atomic layer etching apparatus and method according to the present invention can perform etching with a smooth surface.

The atomic layer etching apparatus and method according to the present invention increase the temperature of the substrate surface by colliding an electron beam having kinetic energy with the target substrate and converting it into thermal energy accompanied by lattice atom vibration at the substrate surface. This method is a useful method capable of increasing the surface temperature in a short time limited only to the surface in the adsorption step of the ALE process. Therefore, by using various methods employing magnetic fields and electric fields, as in the ion collision, the surface collision of the electron beam during the flight of the electron beam can be utilized as a useful method in the adsorption step of the ALE process.

As described above, the atomic layer etching apparatus and method according to the present invention can perform atomic layer etching more efficiently and excellently by simultaneously applying a magnetic field and an electric field to the ion beam or electron beam flying toward the target substrate.

### BRIEF DESCRIPTION OF THE DRAWINGS

FIG. 1 is a schematic diagram illustrating the concept of an atomic layer etching process.

FIG. 2 is a gaussian distribution graph showing the form of ion beam energy distribution extracted from plasma.

FIG. 3 is a schematic diagram showing an ion beam extracted from a plasma source incident vertically on the surface of a target substrate.

FIG. 4 is a schematic diagram defining the incident angle of an ion beam with respect to the surface of a target substrate.

FIG. 5 is a graph showing the relationship between the incident angle of an ion beam according to gas particles and the sputtering yield.

FIG. 6 is a schematic diagram showing that an ion beam extracted from plasma is rotated by a magnetic field applied in a horizontal direction and obliquely incident on the surface of a substrate in an atomic layer etching apparatus according to a preferred embodiment of the present invention,

FIG. 7 is a cross-sectional view showing a grid assembly 10, a ceramic grid 20, and a metal layer 30 in the atomic layer etching apparatus according to the preferred embodiment of the present invention.

FIG. 8 is a side view showing oblique incidence of an ion beam by a first embodiment of a magnetic field applying module in the atomic layer etching apparatus according to the preferred embodiment of the present invention.

FIG. 9A is a top view showing a second embodiment of the magnetic field applying module in the atomic layer etching apparatus according to the preferred embodiment of the present invention.

FIG. 9B is a top view showing control of the inclination direction of the ion beam according to forward, backward, left, and right changes of the magnetic field by the magnetic field applying module according to the second embodiment.

FIGS. 10A and 10B illustrate a third embodiment of the magnetic field applying module in the atomic layer etching apparatus according to the preferred embodiment of the present invention, exemplarily showing the magnetic field applying module installed on the left and right sides of the ion flight space.

FIG. 11 exemplarily shows the magnetic field applying module according to the third embodiment installed at the front, rear, left, and right of the ion flight space.

FIG. 12 illustrates a fourth embodiment of the magnetic field applying module in the atomic layer etching apparatus according to the preferred embodiment of the present invention, exemplarily showing the magnetic field applying module installed above and below the ion flight space.

FIG. 13 illustrates a fifth embodiment of the magnetic field applying module in the atomic layer etching apparatus according to the preferred embodiment of the present invention, exemplarily showing the magnetic field applying module installed beneath the target substrate, which is the lower portion of the ion flight space.

FIG. 14 illustrates a sixth embodiment of the magnetic field applying module in the atomic layer etching apparatus according to the preferred embodiment of the present invention, exemplarily showing the magnetic field applying module installed beneath the target substrate, which is the lower portion of the ion flight space, and an electromagnet coil installed at the upper portion.

FIG. 15 illustrates a seventh embodiment of the magnetic field applying module in the atomic layer etching apparatus according to the preferred embodiment of the present invention, exemplarily showing the magnetic field applying module installed beneath the target substrate, which is the lower portion of the ion flight space, and one or multiple magnet cores rotated across the entire lower portion of the substrate.

FIG. 16 illustrates an eighth embodiment of the magnetic field applying module in the atomic layer etching apparatus according to the preferred embodiment of the present invention, exemplarily showing the magnetic field applying module installed beneath the target substrate, which is the lower portion of the ion flight space, one or multiple magnet cores rotated across the entire lower portion of the substrate, and an electromagnet coil installed at the upper portion.

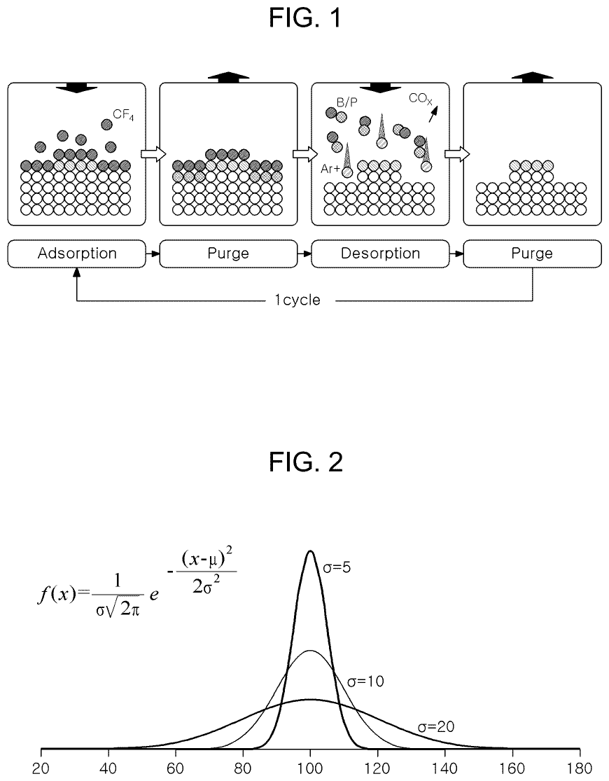

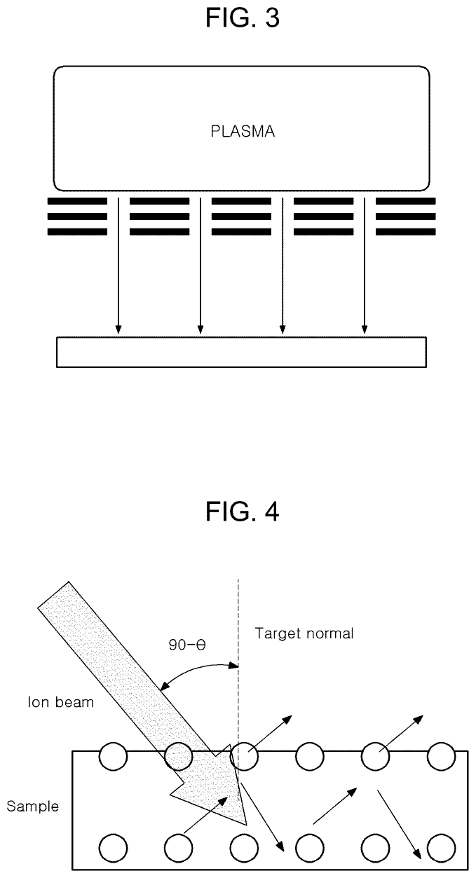

### DETAILED DESCRIPTION OF THE INVENTION

For atomic layer etching, the ion beam must have a single energy value and a low incident angle that enables etching only of the surface atomic layer without causing deep etching. Accordingly, the atomic layer etching apparatus and method according to the present invention are characterized in that atomic layer etching is performed by controlling the charged particles including ions and electrons using a magnetic field and an electric field to adjust the etching rate and the etching depth or to control the energy of the ions. Hereinafter, an atomic layer etching apparatus and an atomic layer etching method according to a preferred embodiment of the present invention will be described in detail with reference to the accompanying drawings.

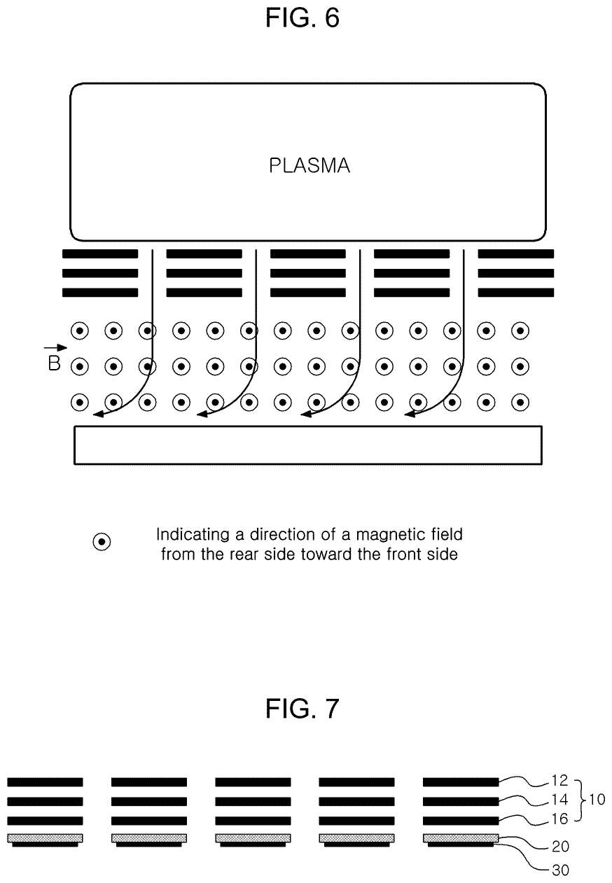

FIG. 6 is a schematic diagram showing that, in the atomic layer etching apparatus according to the preferred embodiment of the present invention, an ion beam extracted from plasma is rotated by a magnetic field applied in a direction perpendicular to the falling direction of the ion beam and is obliquely incident on the surface of a substrate. Here, the direction perpendicular to the falling direction of the ion beam extracted from plasma may mean a direction proceeding from the rear side to the front side of the drawing.

Referring to FIG. 6, the atomic layer etching apparatus according to the preferred embodiment of the present invention includes a plasma source, a grid assembly, and a magnetic field applying module. The atomic layer etching apparatus according to the present invention is configured such that charged particles extracted from plasma are obliquely incident on the surface of a target substrate to etch only a single atomic layer. The atomic layer etching apparatus according to the present invention may further comprise a control module capable of controlling operations of respective components.

The plasma source is equipment that generates and provides plasma. One embodiment of the plasma source may comprise a plasma chamber and an antenna connected to the chamber. Accordingly, the plasma source having the above-described configuration can generate plasma inside the plasma chamber by supplying gas into the plasma chamber and applying RF or microwave power to the antenna disposed outside the chamber. The plasma source is equipment widely known in the art and may be variously designed according to required conditions of the system. Therefore, the plasma source described in this specification is an exemplary embodiment, and the scope of the present invention should not be construed as being limited to the plasma source described in this specification.

FIG. 7 is a cross-sectional view showing a grid assembly 10, a ceramic grid 20, and a metal layer 30 in the atomic layer etching apparatus according to the preferred embodiment of the present invention. Referring to FIG. 7, the atomic layer etching apparatus according to the preferred embodiment of the present invention includes the grid assembly 10 to extract charged particles from plasma. The charged particles may include electrons or ions. Meanwhile, the atomic layer etching apparatus according to the present invention may further include the ceramic grid 20 at the front of the grid assembly 10, so that the charged particles extracted from plasma can fly with linearity. In addition, the atomic layer etching apparatus according to the preferred embodiment of the present invention may further include the metal layer 30 to adjust the potential of the charged particles extracted from plasma.

Referring to FIG. 7, the grid assembly 10 is composed of a plurality of grids to which potentials can be applied, and each grid has a plurality of grid holes. The grid assembly 10 is disposed at the front of the plasma source. The grid assembly 10 is configured to extract charged particles from the plasma of the plasma source by controlling the potentials applied to the grids. One embodiment of the grid assembly may be composed of a combination of a beam grid 12, an acceleration grid 14, and a deceleration grid 16, which are made of a conductive material to which potentials can be applied. The conductive material to which potentials can be applied may include metal and the like. The grid assembly may be arranged in the order of the beam grid, the acceleration grid, and the deceleration grid.

Meanwhile, another embodiment of the grid assembly may be composed of a combination of a beam grid and an acceleration grid. The material forming the grids of the grid assembly to which a potential can be applied may include, in addition to metal, a material that has conductivity while not becoming a contaminant of the substrate when sputtered by colliding with ions of plasma or ions extracted from plasma and flying. Examples thereof may include Si, SiC, Si₃N₄, and graphite.

The beam grid 12 is disposed adjacent to the plasma and is configured to impart energy to charged particles of the plasma. Here, the charged particles may include ions and electrons. The beam grid in contact with the plasma may be applied with a positive (+) potential to float the plasma, and the ions in the plasma can obtain energy corresponding to the floated potential. As a result, ions emitted from the plasma have energy corresponding to the positive (+) potential applied to the beam grid.

The acceleration grid 14 is disposed at a predetermined distance from the beam grid and is configured to extract and accelerate charged particles from the plasma. By applying a negative (−) potential to the acceleration grid, positive (+) ions are extracted from the plasma.

The deceleration grid 16 is disposed at a predetermined distance from the acceleration grid and is configured to decelerate the charged particles extracted from the acceleration grid. By applying a ground potential to the deceleration grid, positive (+) ions that have passed through the acceleration grid and are flying forward toward the target substrate are prevented from being pulled back toward the acceleration grid by the negative (−) potential of the acceleration grid. As a result, while the charged particles are flying toward the substrate, the ion beam does not spread widely. The grid holes of the beam grid, the acceleration grid, and the deceleration grid are arranged in alignment with each other, so that charged particles can be extracted from the plasma through the grid holes of each grid.

The ceramic grid 20 is made of a ceramic material to which no potential can be applied and includes a plurality of grid holes. The ceramic grid is disposed at a predetermined distance from the deceleration grid. Ions extracted from the aforementioned grid assembly fly with a gaussian energy distribution and are widely dispersed. The ceramic grid secures the linearity of the ion beam by selecting only ions flying with linearity among the ions having energy. Accordingly, ion beams having linearity rotate with a constant curvature depending on the strength of the magnetic field, and as a result, can be incident on the target substrate at a preset low angle. In addition, the ceramic grid serves to filter ions having, as a vertical energy component, only the energy applied to the beam grid, thereby securing the linearity of the ion beam and reducing the energy dispersion of the ion beam.

The metal layer 30 is coated and mounted on a surface of the ceramic grid that does not face the grid assembly, and at the same time, may be disposed at a predetermined distance from the sidewalls of the grid holes of the ceramic grid. By applying a positive (+) or negative (−) potential to the metal layer, a positive (+) or negative (−) potential field can be applied to the ion charges flying toward the target substrate after passing through the ceramic grid. As a result, the energy of the ion beam extracted from the plasma through the grid assembly can be precisely controlled by additionally increasing the energy of positive ions extracted from the plasma using the positive (+) potential of the metal layer, or by additionally lowering the energy using the negative (−) potential of the metal layer.

Meanwhile, in the apparatus according to the present invention, one or more additional grids may be selectively arranged in series between the grid assembly and the ceramic grid, thereby more accurately filtering the dispersed angles of the ion beam extracted from the grid assembly and the ceramic grid.

Meanwhile, in the apparatus according to the present invention, the magnetic field applied using the magnetic field applying module to control the charged particles may penetrate into the plasma source and affect the plasma density. Due to fluctuations of the magnetic field caused thereby, a problem may occur in which the plasma density changes. In order to prevent such a problem from occurring and to avoid the influence on the ion beam flux, in the apparatus according to the present invention, the deceleration grid or additional grids may be made of μ-metal capable of shielding the magnetic field or a magnetic material capable of shielding the magnetic field.

Meanwhile, in the apparatus according to the present invention, the charged particles are extracted from the plasma source by a potential applied to the grid module. When a negative (−) potential is applied to the grid module, positive (+) ions can be extracted, and when a positive (+) potential is applied to the grid module, electrons can be extracted. When ions are extracted from the plasma source, an ion beam may be formed and directed toward the target substrate. On the other hand, when electrons are extracted from the plasma source, an electron beam may be formed and directed toward the target substrate. In the apparatus according to the present invention, during an adsorption step, the electrons are extracted from the plasma source using the grid module to provide an electron beam to the target substrate and heat the surface of the target substrate. In addition, during a desorption step, the ions are extracted from the plasma source using the grid module to provide an ion beam to the target substrate and etch the surface of the target substrate.

The magnetic field applying module can apply a magnetic field to the charged particles extracted from the plasma and vertically falling toward a target substrate. By the magnetic field applied by the magnetic field applying module, the vertically falling charged particles can be induced to rotate. Due to the rotation of the charged particles, the charged particles can be obliquely incident on the surface of the target substrate at a preset incident angle. The atomic layer etching apparatus according to the present invention can etch a single atomic layer on the surface of the target substrate by adjusting the incident angle of the charged particles onto the target substrate surface using the magnetic field applying module and colliding the charged particles with the sides of the atoms of the target substrate surface.

The magnetic field applying module may be configured by combining one or more of an electromagnet surrounding a magnet core, a circular or rectangular type Helmholtz coil, a flat electromagnet, and one or multiple magnet cores and coils. The magnetic field applying module may be disposed at one or more of the front, rear, left, right, upper, and lower portions of the space where the magnetic field are required. Hereinafter, various embodiments of the magnetic field applying module of the atomic layer etching apparatus of the present invention will be described with reference to the drawings.

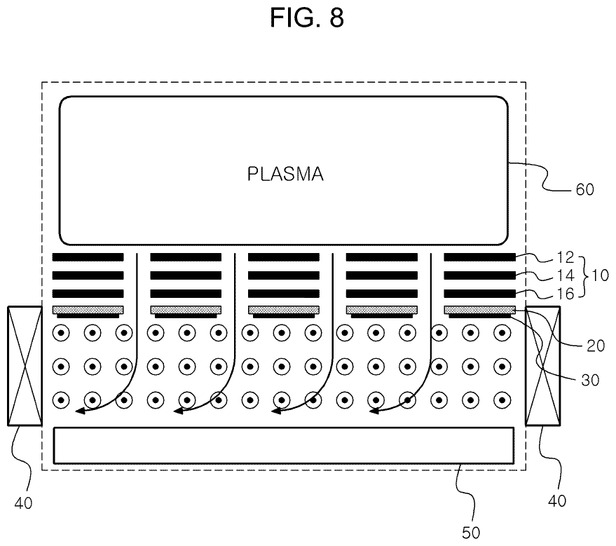

FIG. 8 is a schematic diagram showing a first embodiment of the magnetic field applying module in the atomic layer etching apparatus according to the preferred embodiment of the present invention. Referring to FIG. 8, the first embodiment of the magnetic field applying module 40 according to the present invention may be configured as an electromagnet surrounding a magnet core. The first embodiment of the magnetic field applying module 40 may be disposed at the front and rear or the left and right or at both the front and rear and the left and right of the space where magnetic field lines or the magnetic field are required. Here, the space where magnetic field lines or the magnetic field are required may be a flight space in which the charged particles including the ions or the electrons extracted from plasma 60 through the grid assembly or the ceramic grid coated with the metal layer fly to be incident on the target substrate 50.

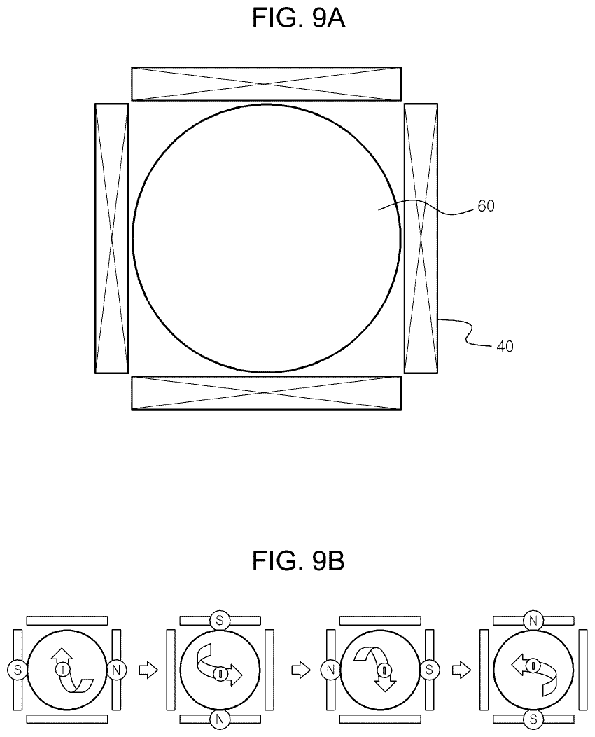

FIG. 9A is a schematic diagram showing a second embodiment of the magnetic field applying module in the atomic layer etching apparatus according to the preferred embodiment of the present invention, and FIG. 9B is a top view showing control of the inclination direction of the ion beam according to the change of the magnetic field direction using the magnetic field applying module according to the second embodiment. As such, when the direction of the ion beam is sequentially changed and obliquely incident at a low incident angle onto the surface of the target substrate, ion collisions in a direction parallel to the surface layer occur from all directions. As a result, not only can the surface of the substrate be etched smoothly, but also a three-dimensional shaped substrate can be efficiently etched, and damage in the depth direction of the substrate can be reduced.

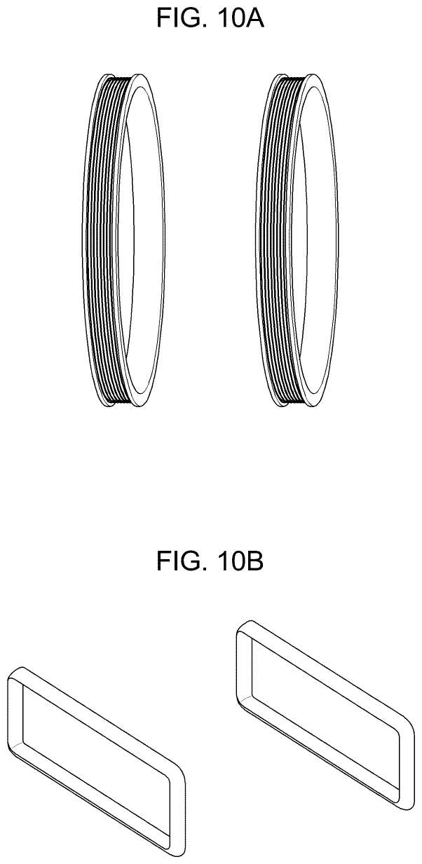

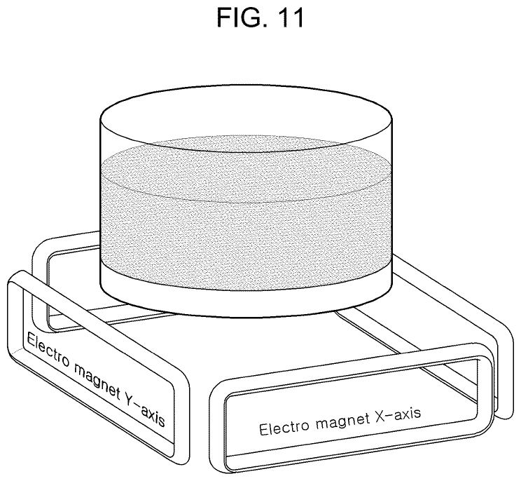

FIGS. 10A and 10B illustrate third embodiments of the magnetic field applying module in the atomic layer etching apparatus according to the preferred embodiment of the present invention. FIG. 11 exemplarily shows the magnetic field applying module, composed of a rectangular type Helmholtz coil as shown in FIG. 10B, disposed at both the front and rear and the left and right of the flight space of the charged particles. The third embodiment of the magnetic field applying module according to the present invention may be composed of a circular type Helmholtz coil as shown in FIG. 10A, or a rectangular type Helmholtz coil as shown in FIG. 10B. The magnetic field applying module according to the third embodiment may be disposed at the front and rear or the left and right or at both the front and rear and the left and right of the flight space of the charged particles where magnetic field lines or the magnetic field are required, as shown in FIG. 11.

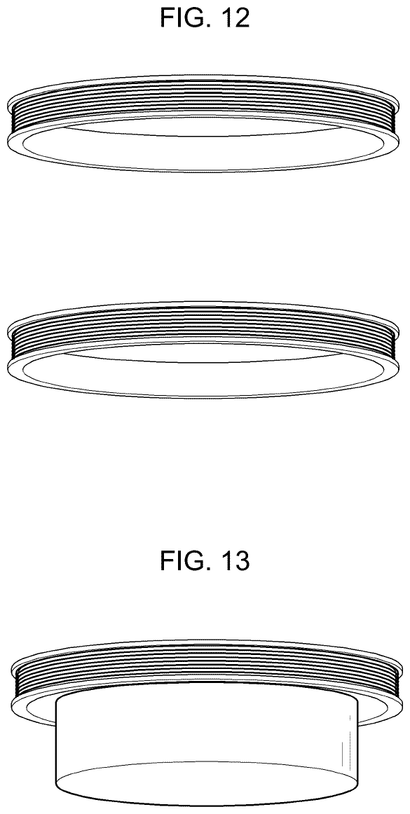

FIG. 12 illustrates a fourth embodiment of the magnetic field applying module in the atomic layer etching apparatus according to the preferred embodiment of the present invention. Referring to FIG. 12, Helmholtz coils may be disposed at the upper and lower portions of flight space of the charged particles where magnetic field lines or the magnetic field are required.

FIG. 13 illustrates a fifth embodiment of the magnetic field applying module in the atomic layer etching apparatus according to the preferred embodiment of the present invention. Referring to FIG. 13, the fifth embodiment of the magnetic field applying module according to the present invention may be composed of an electromagnet coil and an electromagnet core disposed at the lower portion of the flight space of the charged particles. The lower portion of the flight space of the charged particles, as the lower portion of the flight space of the charged particles where magnetic field lines or the magnetic field are required, may be the lower portion of the target substrate.

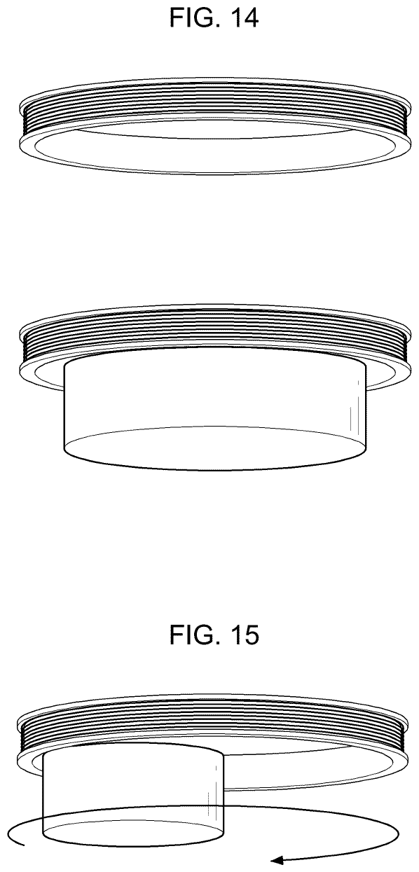

FIG. 14 illustrates a sixth embodiment of the magnetic field applying module in the atomic layer etching apparatus according to the preferred embodiment of the present invention. Referring to FIG. 14, the sixth embodiment of the magnetic field applying module according to the present invention may be composed of an electromagnet coil and an electromagnet core disposed at the lower portion of the flight space of the charged particles, and a circular electromagnet coil disposed at the upper portion of the flight space of the charged particles.

FIG. 15 illustrates a seventh embodiment of the magnetic field applying module in the atomic layer etching apparatus according to the preferred embodiment of the present invention. Referring to FIG. 15, the seventh embodiment of the magnetic field applying module according to the present invention is composed of an electromagnet coil and one or multiple magnet cores disposed at the lower portion of the flight space of the charged particles, and further includes a rotation module configured to rotate one or multiple magnet cores. In the magnetic field applying module according to the seventh embodiment, by rotating the magnet cores using the rotation module, the influence of the magnetic field can be evenly applied to the entire target substrate. The rotation module is configured to include a motor and a rotation transmission unit, and ends of the rotation transmission unit may be connected to the motor and the magnet core, respectively. The rotation module may be configured to transmit rotational force to the magnet core. The rotation transmission unit may be composed of a shaft or a gear. The rotation module is equipment widely known in the art and may be variously designed according to required conditions of the system. Therefore, the configuration of the rotation module described in this specification is an exemplary embodiment, and the scope of the present invention should not be construed as being limited to the configuration of the rotation module described in this specification.

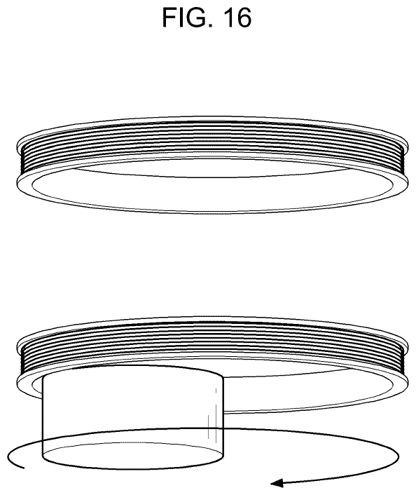

FIG. 16 illustrates an eighth embodiment of the magnetic field applying module in the atomic layer etching apparatus according to the preferred embodiment of the present invention. Referring to FIG. 16, the eighth embodiment of the magnetic field applying module according to the present invention may be composed of one or multiple magnet cores and an electromagnet coil disposed at the lower portion of the flight space of the charged particles, and a circular electromagnet coil disposed at the upper portion of the flight space of the charged particles. In addition, it further includes a rotation module configured to rotate one or multiple magnet cores. In the magnetic field applying module according to the eighth embodiment, by rotating the magnet cores using the rotation module, the influence of the magnetic field can be evenly applied to the entire target substrate.

The control module may be configured using a processor, a microcontroller, a digital signal processor (DSP), a programmable logic controller (PLC), or a field programmable gate array (FPGA). The control module according to the present invention can control operations of the magnetic field applying module, the plasma source, and the grid module according to preset conditions. Accordingly, the atomic layer etching apparatus according to the present invention can precisely adjust a direction and intensity of the magnetic field provided to the flight space of the charged particles by precisely controlling an operation of the magnetic field applying module and the power applied to the magnetic field applying module using the control module. As a result, the atomic layer etching apparatus according to the present invention can precisely adjust an incident angle of the ion beam or the electron beam incident to the surface of the target substrate.

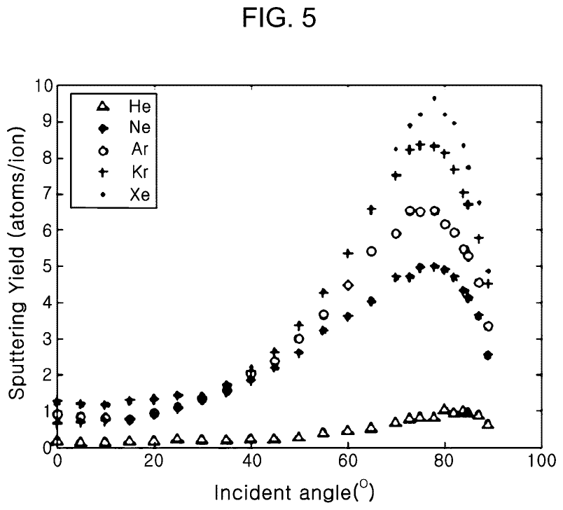

Referring to FIG. 5, it can be seen that the sputter yield according to the angle of the ion beam differs depending on the type of etching gas particles. Accordingly, by selecting the type of the etching gas particles, the etching rate can be adjusted even at the same energy and the same incident angle. As the etching gas, one of He, Ne, Ar, Kr, or Xe may be used. When the etching gas having a small atomic weight is ionized and collided, the momentum is reduced compared to gases having a large atomic weight, thereby decreasing the etching rate. Therefore, by using He or Ne gas with a small atomic weight, the etching rate can be reduced and substrate damage can be decreased. Meanwhile, Kr or Xe gases having a large atomic weight can be used to increase the etching rate.

The atomic layer etching apparatus according to the present invention may further comprise a substrate cooling module. The substrate cooling module may be connected to a target substrate and may be configured to cryogenically cool the target substrate. The substrate cooling module may be constituted by cooling equipment employing an electrostatic chuck (ESC)-based cooling plate having cooling channels, or may be constituted by an external chiller device having cooling water or refrigerant. The substrate cooling module is equipment well known in the art and may be variously designed according to required conditions. Therefore, the configuration of the substrate cooling module described in the present specification is merely an exemplary illustration, and the scope of the present invention should not be construed as being limited to the configuration of the substrate cooling module described herein.

The atomic layer etching apparatus according to the present invention is configured to cryogenically cool a lower surface of the target substrate using the substrate cooling module while irradiating the electron beam onto an upper surface of the target substrate, thereby allowing only the surface temperature of the target substrate to increase even when the electron beam is irradiated.

Hereinafter, an atomic layer etching method using the atomic layer etching apparatus according to the preferred embodiment of the present invention described above will be described in detail.

The atomic layer etching method comprises an adsorption step, a first purging step, a desorption step, and a second purging step, and performs atomic layer etching with respect to the surface of a target substrate. Here, the adsorption step is a step of adsorbing reactive radicals onto the surface of the target substrate to form a surface layer compound on the target substrate. The first purging step is a step of removing residual reactants remaining without reacting after adsorption. The desorption step is a step of etching the surface layer compound of the surface of the target substrate using an ion beam. The second purging step is a step of removing substances desorbed from the surface of the target substrate. Hereinafter, each step will be described in detail.

In the adsorption step, the electron beam is extracted from plasma and irradiated onto the surface of the target substrate by controlling the potentials applied to the grid module and the metal layer of the atomic layer etching apparatus according to the present invention. By applying potentials opposite to those applied in the ion beam extraction process to the grid module and the metal layer, the electron beam can be extracted from the plasma.

Meanwhile, if the energy of the electron beam extracted from plasma is greater than the energy required for the process, the target substrate may be damaged by electron beam collision. Therefore, by applying a magnetic field in a direction perpendicular to the flight direction of the electron beam using the magnetic field applying module, the electron beam is incident on the substrate surface at a low angle. In this way, as the incident angle of the electron beam decreases, the penetration depth of electrons into the substrate surface decreases. As a result, the electrons strike only the surface layer of the substrate, thereby preventing damage to the substrate.

As described above, in the adsorption step, when an electron beam with kinetic energy during flight collides with the substrate, the kinetic energy of the electron beam is converted into thermal energy at the surface of the substrate, thereby raising the temperature of the substrate surface. At this time, by heating the substrate surface and simultaneously cryogenically cooling the rear surface of the substrate, the collision of the electron beam with the substrate surface can heat only the atomic layer of the substrate surface. Therefore, the atomic layer etching method according to the present invention can form a compound by radicals adsorbed on the surface in a short time during the adsorption process of the ALE process by raising the temperature of the substrate surface using the electron beam.

Meanwhile, in the adsorption step, forward and reverse currents are sequentially supplied to the electromagnets comprising the magnetic field applying module, so that the direction of the magnetic field in the flight space of the electron beam can be sequentially changed and applied in the forward and backward direction, the left and right direction, or the forward, backward, left, and right directions. Accordingly, the temperature of the entire surface of the target substrate can be uniformly raised and surface compounds can be uniformly formed. As a result, the atomic layer etching method according to the present invention can uniformly etch the surface atomic layer as a whole, thereby improving surface roughness. Meanwhile, in the adsorption step, by rotating the magnet core located below the target substrate or rotating the target substrate, compounds can be uniformly formed over the entire surface of the substrate. As a result, the atomic layer etching method according to the present invention can uniformly etch the surface atomic layer as a whole.

In the desorption step, a magnetic field in a predetermined direction is applied to the flight space of the ion beam extracted from the plasma and incident on the surface of the target substrate, so that the ion beam is obliquely incident on the surface of the target substrate at a preset incident angle. By applying the magnetic field in the desorption step so that the ion beam is obliquely incident on the target substrate, the etching rate of the ion beam is reduced, thereby enabling etching of only a single atomic layer.

In the desorption step, forward and reverse currents are sequentially supplied to the electromagnets constituting the magnetic field applying module, so that the direction of the magnetic field in the flight space of the ion beam can be sequentially changed and applied in the forward and backward direction, the left and right direction, or the forward, backward, left, and right directions. As a result, etching can be uniformly performed over the entire target substrate, thereby improving surface roughness. Meanwhile, in the desorption step, by rotating the magnet core located below the target substrate or rotating the target substrate, the entire surface of the substrate can be uniformly etched.

While the present invention has been described above with reference to preferred embodiments, this is merely exemplary and not intended to limit the present invention. It will be understood by those skilled in the art that various modifications and applications not exemplified above can be made without departing from the essential characteristics of the present invention. Such modifications and applications should be construed as being included within the scope of the present invention as defined in the appended claims.

What is claimed is:

1. An atomic layer etching apparatus comprising:
a plasma source for generating plasma;
a grid assembly composed of a plurality of grids to which potentials can be applied, disposed in front of the plasma source, and configured to extract charged particles from the plasma of the plasma source by controlling potentials applied to the grids; and
a magnetic field applying module disposed in a region adjacent to a flight space of the charged particles extracted from the plasma, the magnetic field applying module being configured to apply a magnetic field to the flight space of the charged particles,
wherein the magnetic field applying module is configured to apply a magnetic field to the flight space of the charged particles so as to control flight paths of the charged particles, thereby enabling etching of a single atomic layer of a target substrate.

2. The atomic layer etching apparatus according to claim 1, wherein the magnetic field applying module is configured to adjust a strength and direction of the magnetic field applied to the flight space of the charged particles, such that the charged particles are obliquely incident on a surface of the target substrate at a preset incident angle.

3. The atomic layer etching apparatus according to claim 1, wherein the magnetic field applying module is formed by combining one or more of an electromagnet surrounding a magnet core, a circular or rectangular type Helmholtz coil, a flat electromagnet, one or multiple magnet cores and a coil.

4. The atomic layer etching apparatus according to claim 1, wherein the magnetic field applying module is disposed at one or more of a front side, a rear side, a left side, a right side, an upper side, and a lower side of a space where the magnetic field is required.

5. The atomic layer etching apparatus according to claim 1, further comprising a ceramic grid made of a ceramic material to which no potential is applied, the ceramic grid being disposed at a predetermined distance from a front surface of the grid assembly,
wherein the ceramic grid, to which no potential is applied, allows the charged particles extracted from the plasma to fly with uniform energy and linearity.

6. The atomic layer etching apparatus according to claim 5, further comprising a metal layer disposed on one surface of the ceramic grid and disposed at a predetermined distance from grid holes of the ceramic grid,
wherein the atomic layer etching apparatus is configured to apply a potential to the metal layer so as to adjust the potential of the charged particles emitted from the ceramic grid.

7. The atomic layer etching apparatus according to claim 1, wherein the grid assembly comprises:
a beam grid disposed adjacent to the plasma and configured to impart energy to the charged particles of the plasma; and
an acceleration grid disposed at a predetermined distance from the beam grid and configured to extract and accelerate the charged particles from the plasma;
wherein grid holes of the beam grid and the acceleration grid are aligned with each other, and the charged particles are extracted from the plasma through the grid holes of the beam grid and the acceleration grid.

8. The atomic layer etching apparatus according to claim 7, further comprising a deceleration grid disposed at a predetermined distance from the acceleration grid, made of μ-metal capable of shielding a magnetic field or a magnetic material capable of shielding a magnetic field and configured to decelerate the charged particles extracted from the acceleration grid;
wherein grid holes of the beam grid, the acceleration grid, and the deceleration grid are aligned with each other, and the charged particles are extracted from the plasma through the grid holes of the beam grid, the acceleration grid, and the deceleration grid.

9. The atomic layer etching apparatus according to claim 5, further comprising one or more additional grids disposed between the grid assembly and the ceramic grid and made of μ-metal capable of shielding a magnetic field or a magnetic material capable of shielding a magnetic field,
wherein the additional grids are configured to improve linearity of ions extracted from the grid assembly.

10. The atomic layer etching apparatus according to claim 1, wherein the grids included in the grid assembly are made of one material selected from a conductive metal, Si, SiC, Si₃N₄, and graphite.

11. The atomic layer etching apparatus according to claim 1, wherein a gas supplied to the plasma source is selected from one of He, Ne, Ar, Kr, and Xe according to energy required for atomic layer etching of the target substrate.

12. The atomic layer etching apparatus according to claim 1, further comprising a substrate cooling module configured to cool the target substrate,
wherein the apparatus is configured to cool the target substrate while irradiating an electron beam onto a surface of the target substrate, such that only the surface temperature of the target substrate increases even when the electron beam is irradiated.

13. An atomic layer etching apparatus comprising:
a plasma source for generating plasma;
a grid assembly composed of a plurality of grids to which potentials can be applied, disposed in front of the plasma source, and configured to extract charged particles from the plasma of the plasma source by controlling potentials applied to the grids; and
a ceramic grid made of a ceramic material to which no potential is applied, disposed at a predetermined distance from a front surface of the grid assembly;
wherein the ceramic grid, to which no potential is applied, allows the charged particles extracted from the plasma by the grid assembly to fly with uniform energy and linearity toward a target substrate so as to perform atomic layer etching of a target substrate.

14. The atomic layer etching apparatus according to claim 13, further comprising a metal layer disposed on one surface of the ceramic grid and disposed at a predetermined distance from the grid holes of the ceramic grid,
wherein the atomic layer etching apparatus is configured to apply a potential to the metal layer so as to control the potential of the charged particles emitted from the ceramic grid.

15. The atomic layer etching apparatus according to claim 13, wherein the grid assembly comprises:
a beam grid disposed adjacent to the plasma and configured to impart energy to the charged particles of the plasma;
an acceleration grid disposed at a predetermined distance from the beam grid and configured to extract and accelerate the charged particles from the plasma, and
a deceleration grid disposed at a predetermined distance from the acceleration grid and configured to decelerate the charged particles extracted from the acceleration grid;
wherein grid holes of the beam grid, the acceleration grid, and the deceleration grid are aligned with each other, and the charged particles are extracted from the plasma through the grid holes of the beam grid, the acceleration grid, and the deceleration grid.

16. An atomic layer etching method comprising the steps of:
(a) adsorbing reactive radicals on a surface of a target substrate to form a surface layer compound on the target substrate;
(b) removing residual reactants remaining unreacted after adsorbing;
(c) etching the surface of the target substrate using an ion beam to desorb the surface layer compound from the target substrate; and
(d) removing a material desorbed from the target substrate;
wherein in step (c), a magnetic field having a preset direction and strength is applied to a flight space of the ion beam extracted from plasma and incident on the surface of the target substrate, such that the ion beam is obliquely incident on the surface of the target substrate at a preset incident angle.

17. The atomic layer etching method according to claim 16, wherein in step (c), the ion beam is obliquely incident on the surface of the target substrate while sequentially changing a direction of the magnetic field applied to the flight space of the ion beam, thereby uniformly etching the surface of the target substrate.

18. The atomic layer etching method according to claim 16, wherein step (a) comprises:
(a1) extracting an electron beam from plasma; and
(a2) applying a magnetic field having a preset direction to a flight space of the electron beam extracted from the plasma so that the electron beam is obliquely incident on the surface of the target substrate at a preset incident angle;
wherein the surface temperature of the target substrate is raised by the electron beam obliquely incident on the surface of the target substrate.

19. The atomic layer etching method according to claim 18, wherein in step (a2), the electron beam is obliquely incident on the surface of the target substrate while sequentially changing a direction of the magnetic field applied to the flight space of the electron beam, thereby uniformly raising the surface temperature of the target substrate.

20. The atomic layer etching method according to claim 18, wherein step (a) further comprises: (a4) cooling the target substrate while obliquely irradiating the electron beam onto the surface of the target substrate;
thereby raising only a surface temperature of the target substrate and forming a surface layer compound by bonding of only surface atoms of the target substrate.
